(19) United States
(12) Patent Application Publication
(10) Pub. No.: US 2021/0034100 A1
(43) Pub. Date: Feb. 4, 2021

(54) BLACK DEADFRONT FOR DISPLAYS AND RELATED DISPLAY DEVICE AND METHODS

(71) Applicant: CORNING INCORPORATED, Corning, NY (US)

(72) Inventors: Antoine D. LESUFFLEUR, Fontainebleau (FR); Xu OUYANG, Painted Post, NY (US); Yawei SUN, Elmira, NY (US)

(73) Assignee: Corning Incorporated, Corning, NY (US)

(21) Appl. No.: 16/647,305

(22) PCT Filed: Sep. 12, 2018
(86) PCT No.: PCT/US2018/050574

§ 371 Date: Mar. 13, 2020

Related U.S. Application Data
(60) Provisional application No. 62/557,972, filed on Sep. 13, 2017.

(51) Int. Cl. G06F 1/16; G02F 1/1335; H01L 51/52; B60K 37/02

(52) U.S. Cl. CPC G06F 1/1609; G02F 1/133512; B60K 2370/1523; B60K 37/02; B60K 2370/28; H01L 51/5284

(57) ABSTRACT

Embodiments of a deadfront article for a display are disclosed herein. The deadfront article includes a substrate having a first surface and a second surface opposite the first surface. Also included is a semitransparent black layer disposed onto at least a first portion of the second surface of the substrate. The semitransparent black layer is configured to obscure the display when the display is inactive and to allow viewing of the display when the display is active.

### CROSS-REFERENCE TO RELATED APPLICATIONS

This application claims the benefit of priority under 35 U.S.C. § 119 of U.S. Provisional Application Ser. No. 62/557,972 filed on Sep. 13, 2017, the content of which is relied upon and incorporated herein by reference in its entirety.

### TECHNICAL FIELD

The disclosure relates to a deadfront article for a display, and more particularly to vehicle interior systems including a deadfront article for a display and methods for forming the same.

### BACKGROUND

In various applications involving displays, it is desirable to have a display surface or functional surface having a deadfront appearance. In general, a deadfront appearance is a way of hiding a display or functional surface such that there is a seamless transition between a display and a non-display area, or between the deadfronted area of an article and non-deadfronted area or other surface. For example, in a typical display having a glass or plastic cover surface, it is possible to see the edge of the display (or the transition from display area to non-display area) even when the display is turned off. However, it is often desirable from an aesthetic or design standpoint to have a deadfronted appearance such that, when the display is off, the display and non-display areas present as indistinguishable from each other and the cover surface presents a unified appearance. One application where a deadfront appearance is desirable is in automotive interiors, including in-vehicle displays or touch interfaces, as well as other applications in consumer mobile or home electronics, including mobile devices and home appliances. However, it is difficult to achieve both a good deadfront appearance and, when a display is on, a high-quality display.

### SUMMARY

One embodiment of the disclosure relates to a deadfront article for a display. The deadfront article includes a substrate having a first surface and a second surface opposite the first surface. In one or more embodiments, the deadfront article includes a semitransparent black layer disposed onto at least a first portion of the second surface of the glass layer. In one or more embodiments, the semitransparent black layer is configured to obscure the display when the display is inactive and to allow viewing of the display when the display is active.

Another embodiment of the disclosure relates to a device having a deadfront article. The device includes a substrate, a semitransparent black layer printed on a first surface of the substrate, and a light source positioned on a same side of the substrate as the first surface such that the semitransparent black layer is located between the substrate and the light source. The semitransparent black layer is printed onto the second surface of the substrate with a printer using a CMYK color model. In one or more embodiments, the device includes a vibration motor configured to provide haptic feedback when activated (e.g., when the substrate is touched by a user).

Another embodiment of the disclosure relates to a method of forming a curved deadfront article for a display. The method includes the step of curving a deadfront article on a support having a curved surface. The deadfront article includes a glass layer and a semitransparent black layer printed onto a first surface of the glass layer with a printer using a CMYK color model. The method also includes the step of securing the curved deadfront article to the support such that the deadfront conforms to the curved surface of the support. During curving and securing the deadfront article, a maximum temperature of the deadfront article is less than a glass transition temperature of the glass layer.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is a perspective view of a vehicle interior with vehicle interior systems utilizing a deadfront article according to one or more of the embodiments discussed herein.

FIG. 2 shows a display with a deadfront article with the display turned off, according to an exemplary embodiment.

FIG. 3 shows the display with deadfront article of FIG. 2 with the display turned on, according to an exemplary embodiment.

FIG. 4 is a side cross-sectional view of a deadfront article for a display, according to an exemplary embodiment.

FIG. 5 is a side cross-sectional view of a display affixed or mounted to a deadfront article, according to an exemplary embodiment.

FIG. 6 depicts sections of a deadfront article having a semitransparent black layer printed there on with varying levels of K ink, according to an exemplary embodiment.

FIG. 7 depicts the CMYK color model used to print the semitransparent black layer on the glass layer to form the deadfront article, according to an exemplary embodiment.

FIG. 8 depicts how reflectance from the deadfront article was measured.

FIG. 9 is a graph of the reflectance of light across the visible spectrum from embodiments of the deadfront articles having varying levels of K ink.

FIG. 10 depicts the CIE L*a*b* color space used to measure the lightness of the semitransparent black layer printed on the substrate, according to an exemplary embodiment.

FIG. 11 is a graph showing the reflectance of light across the visible spectrum from embodiments of the deadfront articles based on the lightness level of the semitransparent black layer.

FIG. 12 is a photograph of sections of embodiments of deadfront articles having semitransparent black layers of varying lightness values.

FIG. 13 is a graph of the transmittance of light across the visible spectrum from embodiments of the deadfront articles having varying levels of K ink.

FIG. 14 is a graph showing the transmittance of light across the visible spectrum from embodiments of the deadfront articles based on the lightness level of the semitransparent black layer.

FIGS. 15A-15F are micrographs of printed semitransparent black layers at varying levels of lightness.

FIG. 16 depicts a deadfront article obscuring a smartphone when the smartphone display is inactive, according to an exemplary embodiment.

FIG. 17 depicts the deadfront article of FIG. 16 in which the smartphone screen is active and visible through the deadfront display.

FIG. 18 is a side view of a curved glass deadfront article for use with a display, according to an exemplary embodiment.

FIG. 19 is a front perspective view of a glass layer for the glass deadfront of FIG. 6 prior to curve formation, according to an exemplary embodiment.

FIG. 20 shows a curved glass deadfront article shaped to conform with a curved display frame, according to an exemplary embodiment.

FIG. 21 shows a process for cold forming a glass deadfront article to a curved shape, according to an exemplary embodiment.

FIG. 22 shows a process for forming a curved glass deadfront article utilizing a curved glass layer, according to an exemplary embodiment.

### DETAILED DESCRIPTION

Referring generally to the figures, vehicle interior systems may include a variety of different curved surfaces that are designed to be transparent, such as curved display surfaces, and the present disclosure provides articles and methods for forming these curved surfaces. In one or more embodiments, such surfaces are formed from glass materials or from plastic materials. Forming curved vehicle surfaces from a glass material may provide a number of advantages compared to the typical curved plastic panels that are conventionally found in vehicle interiors. For example, glass is typically considered to provide enhanced functionality and user experience for many curved cover material applications, such as display applications and touch screen applications, compared to plastic cover materials.

Further, it is considered desirable in many applications to equip displays, and particularly displays for vehicle interior systems, with a deadfront appearance. In general, a deadfront appearance blocks visibility of underlying display components, icons, graphics, etc. when the display is off, but allows display components to be easily viewed when the display is on or activated (in the case of a touch-enabled display. In addition, an article that provides a deadfront effect (i.e., a deadfront article) can be used to match the color or pattern of the article to adjacent components to eliminate the visibility of transitions from the article to the surrounding components. This can be especially useful when the deadfront article is a different material from the surrounding components (e.g., the deadfront article is formed from a glass material but surrounded by a leather-covered center console). For example, a deadfront article may have a wood grain pattern or a leather pattern can be used to match the appearance of the display with surrounding wood or leather components of a vehicle interior system (e.g., a wood or leather dashboard) in which the display is mounted.

Various embodiments of the present disclosure relate to the formation of a curved glass-based deadfront article utilizing a cold-forming or cold-bending process. As discussed herein, curved glass-based deadfront articles and processes for making the same are provided that avoid the deficiencies of the typical glass hot-forming process. For example, hot-forming processes are energy intensive and increase the cost of forming a curved glass component, relative to the cold-bending processes discussed herein. In addition, hot-forming processes typically make application of glass coating layers, such as deadfront ink or pigment layers, more difficult. For example, many ink or pigment materials cannot be applied to a flat piece of glass material prior to the hot-forming process because the ink or pigment materials typically will not survive the high temperatures of the hot-forming process. Further, application of an ink or pigment material to surfaces of a curved glass article after hot-bending is substantially more difficult than application to a flat glass article.

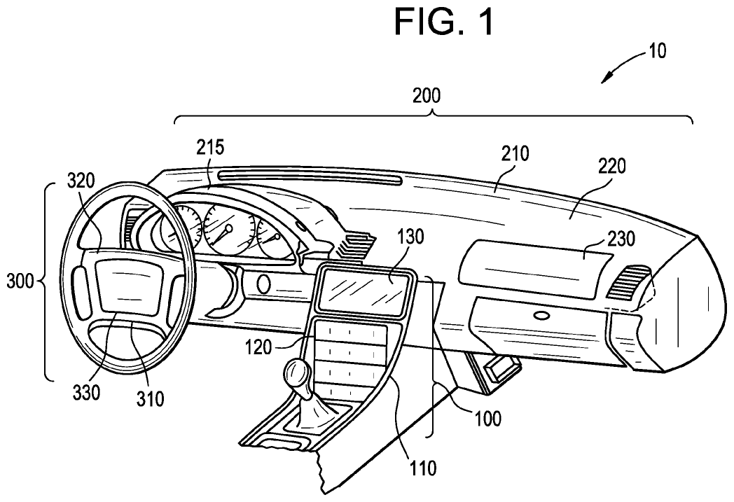

FIG. 1 shows a vehicle interior 10 that includes three different vehicle interior systems 100, 200, 300, according to an exemplary embodiment. Vehicle interior system 100 includes a center console base 110 with a curved surface 120 including a display, shown as curved display 130. Vehicle interior system 200 includes a dashboard base 210 with a curved surface 220 including a display, shown curved display 230. The dashboard base 210 typically includes an instrument panel 215 which may also include a curved display. Vehicle interior system 300 includes a dashboard steering wheel base 310 with a curved surface 320 and a display, shown as a curved display 330. In one or more embodiments, the vehicle interior system may include a base that is an arm rest, a pillar, a seat back, a floor board, a headrest, a door panel, or any portion of the interior of a vehicle that includes a curved surface.

The embodiments of the deadfront articles described herein can be used in any or all of vehicle interior systems 100, 200 and 300. While FIG. 1 shows an automobile interior, the various embodiments of the vehicle interior system may be incorporated into any type of vehicle such as trains, automobiles (e.g., cars, trucks, buses and the like), seacraft (boats, ships, submarines, and the like), and aircraft (e.g., drones, airplanes, jets, helicopters and the like), including both human-piloted vehicles, semi-autonomous vehicles and fully autonomous vehicles. Further, while the description herein relates primarily to the use of the deadfront embodiments used in vehicle displays, it should be understood that various deadfront embodiments discussed herein may be used in any type of display application.

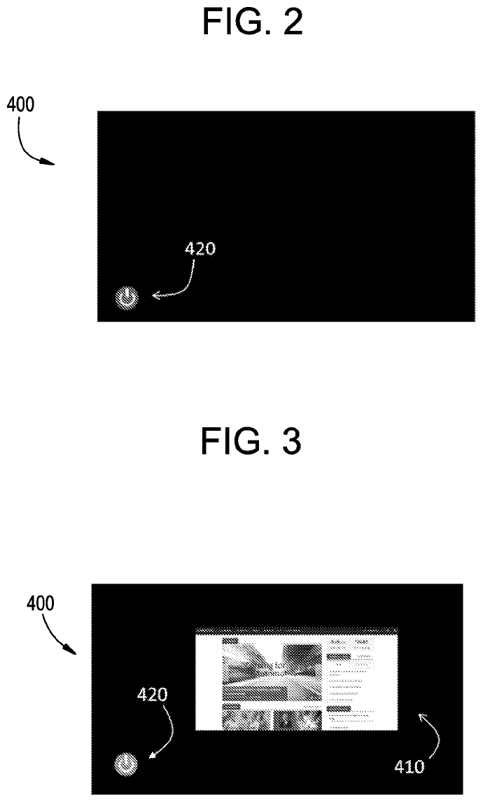

Referring to FIG. 2 and FIG. 3, a deadfront article 400 for a vehicle display, such as displays 130, 230 and/or 330, is shown and described. FIG. 2 shows the appearance of deadfront article 400 when a light source of the associated display is inactive, and FIG. 3 shows the appearance of deadfront article 400 when a light source of the associated display is active. As shown in FIG. 3, with the light source activated, a graphic 410 and/or a plurality of icons are visible through the deadfront article. When the light source is inactivated, the graphic 410 disappears, and deadfront article 400 presents a surface showing a desired surface finish (e.g., a black surface in FIG. 2) that is unbroken by graphics 410. In embodiments, the light source is activated using a power button 420. As shown in the embodiments of FIGS. 2 and 3, the power button 420 is lighted and changes from red to green when activated.

As used herein, the term “active” in reference to a display refers to a state where the display is producing an image to be viewed or optionally viewable by a user. The term “inactive,” as used herein in reference to a display, refers to a state where the display is not producing an image or is not intended to be seen or viewed by a user.

As will be discussed in more detail below, deadfront article 400 provides this differential icon display by utilizing one or more colored layers located between an outer glass layer and a light source. The optical properties of the colored layer are designed such that when the light source is turned off the borders of the icons or other display structures beneath the colored layer are not visible, but when the light source is on, graphics 410 are visible. In various embodiments, the deadfront articles discussed herein are designed to provide a high quality deadfront article, including high contrast icons with the light source on, combined with a uniform deadfront appearance when the light is off. Further, Applicant provides these various deadfront articles with materials suitable for cold forming to curved shapes, including complex curved shapes, as discussed below.

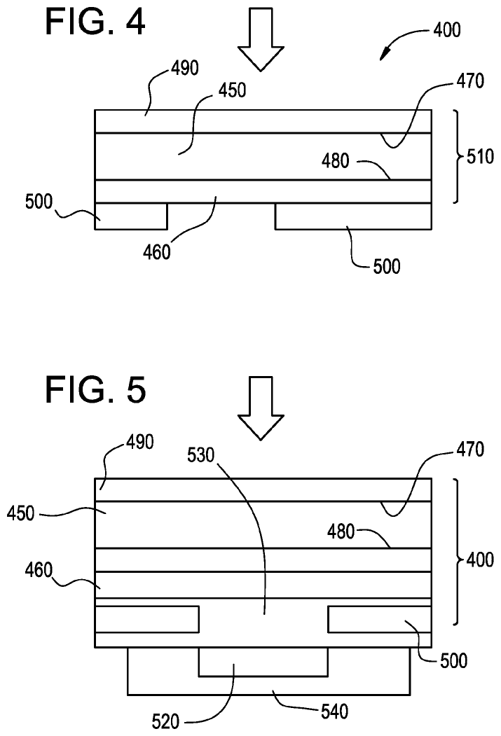

Referring now to FIG. 4, an embodiment of the structure of the deadfront article 400 is provided. In particular, the deadfront article 400 includes at least a substrate 450 and a semitransparent black layer 460. The substrate 450 has an outer surface 470 facing a viewer and an inner surface 480 upon which the semitransparent black layer 460 is, at least in part, disposed. As used herein, the term “dispose” includes coating, depositing and/or forming a material onto a surface using any known method in the art. The disposed material may constitute a layer, as defined herein. As used herein, the phrase “disposed on” includes the instance of forming a material onto a surface such that the material is in direct contact with the surface and also includes the instance where the material is formed on a surface, with one or more intervening material(s) is between the disposed material and the surface. The intervening material(s) may constitute a layer, as defined herein. The term “layer” may include a single layer or may include one or more sub-layers. Such sub-layers may be in direct contact with one another. The sub-layers may be formed from the same material or two or more different materials. In one or more alternative embodiments, such sub-layers may have intervening layers of different materials disposed therebetween. In one or more embodiments a layer may include one or more contiguous and uninterrupted layers and/or one or more discontinuous and interrupted layers (i.e., a layer having different materials formed adjacent to one another). A layer or sub-layers may be formed by any known method in the art, including discrete deposition or continuous deposition processes. In one or more embodiments, the layer may be formed using only continuous deposition processes, or, alternatively, only discrete deposition processes.

While the specifics of the substrate 450 will be discussed in greater detail below, in embodiments the glass layer 450 has a thickness of from 0.05 to 2.0 mm. In one or more embodiments, the substrate may be a transparent plastic, such as PMMA, polycarbonate and the like, or may be a glass material (which may be optionally strengthened). As will also be discussed more fully below, in embodiments the semitransparent black layer 460 is printed onto the inner surface 480 of the substrate 450.

In certain embodiments, the deadfront 400 also includes a functional surface layer 490 and/or an opaque layer 500. The functional surface layer 490 can be configured to provide one or more of a variety of functions. In another exemplary embodiment, the functional surface layer 490 is an optical coating configured to provide easy-to-clean performance, anti-glare properties, antireflection properties, and/or half-mirror coating. Such optical coatings can be created using single layers or multiple layers. In the case of anti-reflection functional surface layers, such layers may be formed using multiple, layers having alternating high refractive index and low refractive index. Non-limiting examples of low refractive index films include SiO₂, MgF₂, and Al₂O₃, and non-limiting examples of high refractive index films include Nb₂O₅, TiO₂, ZrO₂, HfO₂, and Y₂O₃. In embodiments, the total thickness of such an optical coating (which may be disposed over an anti-glare surface or a smooth substrate surface) is from 5 nm to 750 nm. Additionally, in embodiments, the functional surface layer 490 that provides easy-to-clean performance also provides enhanced feel for touch screens and/or coating/treatments to reduce fingerprints. In some embodiments, functional surface layer 500 is integral to the first surface of the substrate. For example, such functional surface layers can include an etched surface in the first surface of the substrate 450 providing an anti-glare surface (or haze of from, e.g., 2% to 20%). The functional surface layer 490, if provided, along with the glass layer 450 and semitransparent black layer 460 together comprise the semi-transparent structure 510 of the deadfront article 400.

The opaque layer 500 has high optical density, e.g., optical density of greater than 3, in order to block light transmittance. In embodiments, the opaque layer 500 is used to block light from transmitting trough certain regions of the deadfront article 400. In certain embodiments, the opaque layer 500 obscures functional or non-decorative elements provided for the operation of the deadfront article 400. In other embodiments, the opaque layer 500 is provided to outline backlit icons and/or other graphics (such as the power button 420 shown in FIGS. 2 and 3) so as to increase the contrast at the edges of such icons and/or graphics. The opaque layer 500 can be any color; in particular embodiments, though, the opaque layer 500 is black or gray. In embodiments, the opaque layer 500 is applied via screen printing or inkjet printing over the semitransparent black layer 460 and/or over the inner surface 480 of the substrate 450. Generally, the thickness of an inkjet-printed opaque layer 500 is from 1 μm to 5 μm, whereas the thickness of a screen-printed opaque layer 500 is from 5 μm to 20 μm. Thus, a printed opaque layer 500 can have a thickness in the range of from 1 μm to 20 μm. However, in other embodiments, the opaque layer 500 is a metal layer deposited via physical vapor deposition and/or is an optical stack produced using the high/low index stacking discussed above for color matching.

As shown in FIG. 5, the deadfront article 400 is placed over or in front of a display 520. In one or more embodiments, the display may include a touch-enabled displays which include a display and touch panel. Exemplary displays include LED display, a DLP MEMS chip, LCDs, OLEDs, transmissive displays and the like. In embodiments, the display 520 is affixed or mounted to the deadfront article 400 using, e.g., an optically clear adhesive 530. The deadfront article 400 has an average transmittance from about 1% to about 40% along the visible spectrum, i.e., a wavelength range from 400 nm to 700 nm. In other words, the deadfront article 400 exhibits an average light transmittance in a range from about 1% to about 40% along the entire wavelength range from about 400 nm to about 700 nm. As used herein, the term “transmittance” is defined as the percentage of incident optical power within a given wavelength range transmitted through a material (e.g., the deadfront article, the substrate or the layers thereof). In embodiments, the deadfront article 400 is a low transmittance deadfront article exhibiting an average transmittance of about 10% or less. In such instances, the opaque layer 500 may not be necessary to obscure the edges of the display 520, i.e., non-display regions 540, and/or wiring, connectors, etc. In other embodiments, the deadfront article 400 is a high transmittance deadfront article which exhibits an average transmittance from about 10% to 40% along the visible spectrum. In such embodiments, the opaque layer 500 may be necessary to block non-display regions 540 from being seen.

Having described generally the structure of the deadfront article 400, attention will be turned to the semitransparent black layer 460. As mentioned above, the semitransparent black layer 460 is, in embodiments, printed on the glass layer 450. In embodiments, the semitransparent black layer 460 is printed using a CMYK color model. The ink used for printing the semitransparent black layer 460 can be thermal or UV cured ink.

In particular, the ink is composed of at least one or more colorants and a vehicle. The colorants can be soluble or insoluble in the vehicle. In embodiments, the colorants are dry colorants in the form of a fine powder. Such fine powders have particles that are, in embodiments, from 10 nm to 500 nm in size. Using the CMYK color model, the colorant provides cyan, magenta, yellow, and/or key (black) colors. The colorants are dissolved or suspended in the vehicle.

The vehicle can serve as a binder to create adhesion to the surface upon which the ink is applied. Further, in embodiments, additives are included in the vehicle specifically for the purpose of improving adhesion to glass/plastic surfaces. Non-limiting examples of vehicles for the colorant include propylene glycol monomethyl ether, diethylene glycol diethyl ether, dimethylacetamide, and toluene. Generally, such vehicles solidify at temperatures from 80° C. to 200° C. In embodiments, the ink includes from 0.5%-6% by volume of the colorant and 94%-99.5% by volume of the vehicle.

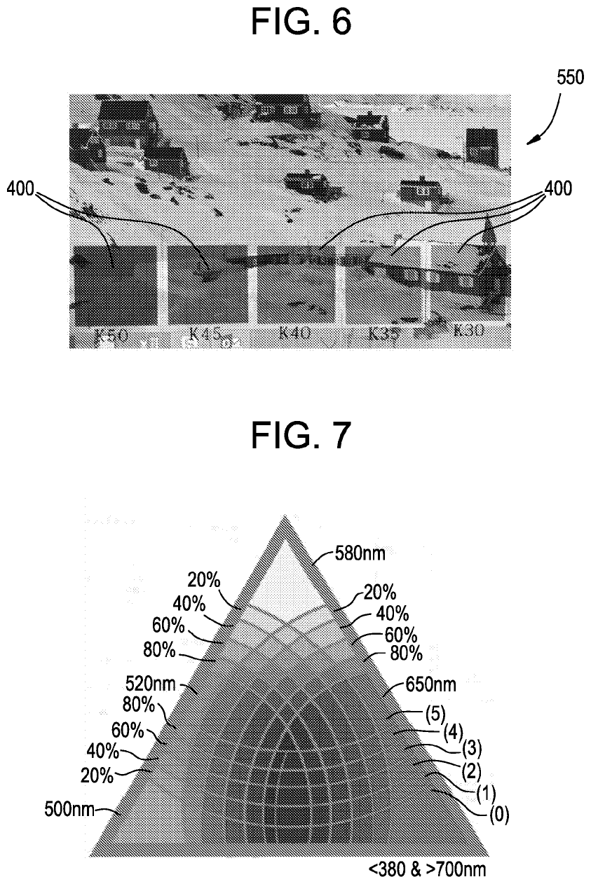

FIG. 6 provides examples of small sections of deadfronts 400 having various thickness of the semitransparent black layer 460 printed thereon. In this embodiment, the semitransparent black layer 460 was printed using only black ink (K ink available from 3MACJET Technology, Co., Ltd., Tainan City, ROC). Thus, each small section of deadfront 400 in FIG. 6 has a different amount of black ink, referred to by the K-values K50, K45, K40, K35, and K30. The K50 deadfront has the most black ink, while the K30 deadfront has the least black ink. The sections of deadfront 400 were placed over a computer monitor 550 to demonstrate light transmission through the deadfront 400. As can be seen, the transmission of light from the monitor 550 decreases with increasing K-value. However, the K ink has selectively stronger absorption at shorter wavelength, causing transmission image color to appear brownish as shown in FIG. 6.

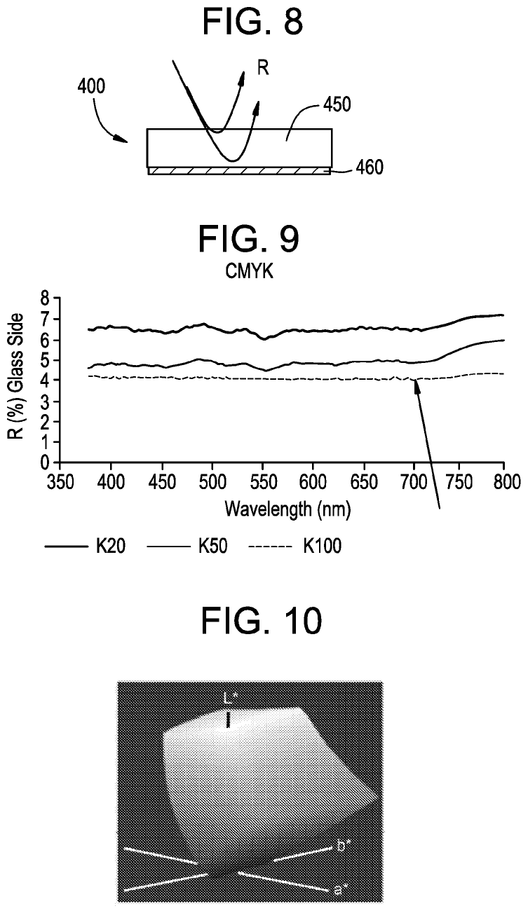

Accordingly, semitransparent black layers 460 were printed using neutral black according to the CMYK color model. FIG. 7 depicts the CMYK color model, including the relative amount of CMY used to produce various colors. As can be seen in FIG. 7, a composite black can be created using just CMY. Rich black in the CMYK color model is produced by first printing a CMY layer over which a black (K) layer is applied. Thus, all the CMYK inks are used as opposed to just the K ink as in the previous embodiment. Deadfronts 400 were produced having various K-values, and the reflectance R of these deadfronts 400 was measured. As can be seen in FIG. 8, the reflectance R includes both the reflectance from the glass layer 450 and the semitransparent black layer 460. The refelectance R from deadfronts 400 having K20, K50, and K100 are shown in FIG. 9. As can be seen, the reflectance R is relatively flat between the wavelengths of 400 nm and 700 nm. At a K-value of 20%, the reflectance R is generally below 7%, and much of that reflectance (approximately 3.9%-4%) is from the glass layer 450.

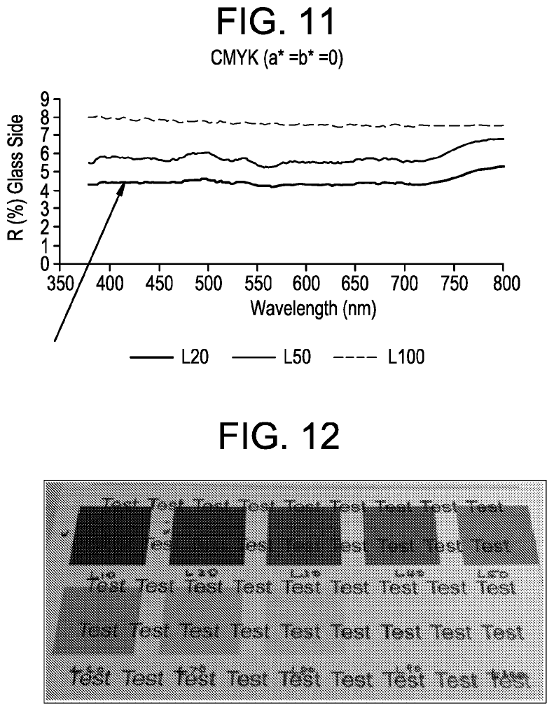

FIG. 10 depicts the CIE L*a*b* color space. L* refers to the lightness, which varies from 0 to 100 with L*=0 being darkest black and L*=100 being brightest white. The a* axis represents red (+a*) and green (−a*), and the b* axis represents yellow (+b*) and blue (−b*). Here, for neutral black, the a* and b* values were set at 0 (i.e., a*=b*=0). In one or more embodiments, one or both the a* and b* values may be in a range from about −2 to about 2. The lightness L* values were then varied between 0 and 100 with reflectance R measurements being taken for L*=20, L*=50, and L*=100. As shown in FIG. 11, the reflectance curves were again substantially flat between the wavelengths of 400 nm and 700 nm. Further, the level of reflectance increased with increasing L*.

FIG. 12 demonstrates the transmittance of several glass layers 450 having printed thereon semitransparent black layers 460 of varying L* levels. These deadfronts article 400 were overlaid a sheet of paper on which the word “Test” was printed for the purposes of observing how well the deadfront article 400 obscured the underlying paper. Beginning in the lower right corner of FIG. 12, the deadfront article 400 was printed at a lightness level of L*=100, and the deadfront article 400 is almost entirely transparent. As the lightness level decreases right-to-left along the bottom row and right-to-left along the top row, the deadfront article 400 obscures more of the underlying paper. In embodiments, the lightness level L* is from 0 to 40 for the deadfront. In particular embodiments, the lightness level L* is from 5 to 20.

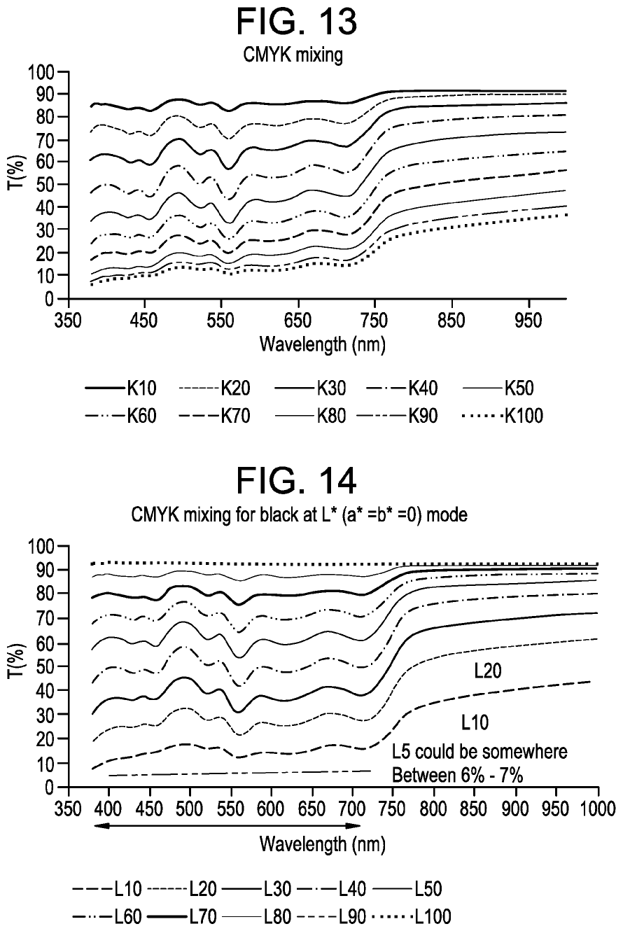

The transmittance of the deadfronts article 400 having various K-values and L* levels is shown in FIGS. 13 and 14. Referring first to FIG. 13, the transmittance T of a particular deadfront decreases with increasing K-value. While varying somewhat more than the reflectance curves, the transmittance curves are still substantially flat over the visible spectrum (i.e., wavelength of 400 nm to 700 nm). In particular embodiments, the K-value is selected to be at least 50%. In other embodiments, the K-value is selected to be at least 75%.

Referring now to FIG. 14, the transmittance T is shown based on the lightness level L*. As can be seen, the transmittance T increases with increasing lightness L*. Again, while not as flat as the reflectance curves, the transmittance curves are still substantially flat over the visible spectrum (i.e., wavelength of 400 nm to 700 nm). Further, based on the downward trajectory in transmittance with decreasing lightness L*, the inventors surmise that a lightness level L*=5 would have a transmittance somewhere between 5% and 7% over the visible spectrum.

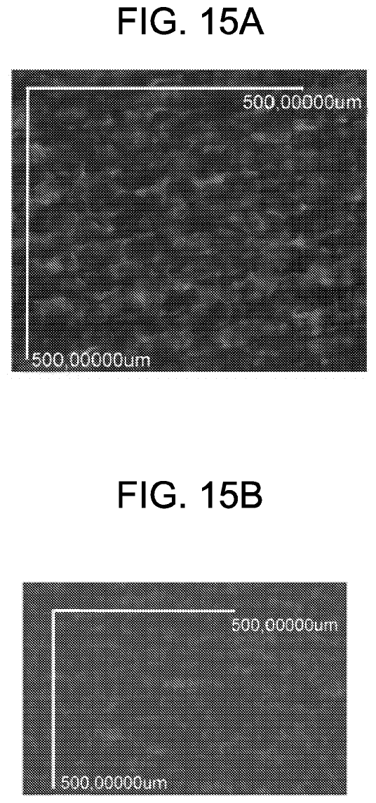

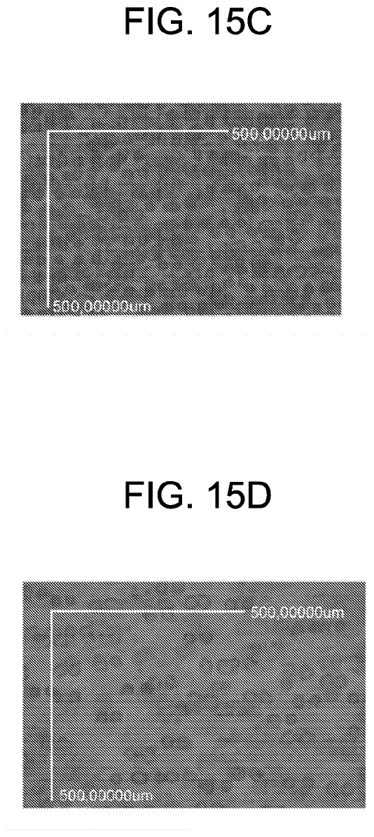

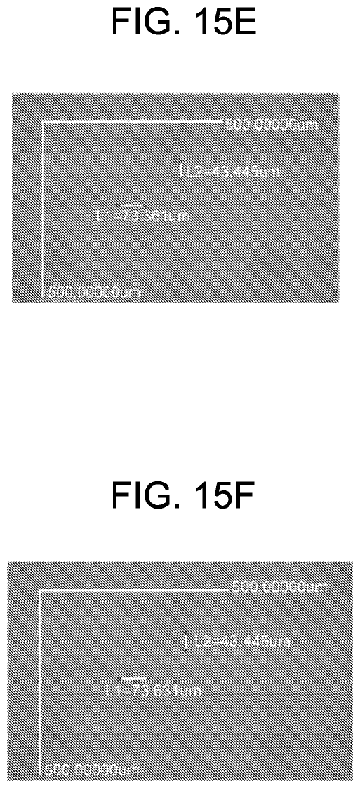

In order to show the actual deposition of the semitransparent black layer 460 on the glass layer 450, a series of micrographs are provided in FIGS. 15A-15F. In particular, the lightness level is shown for L*=5 (FIG. 15A), L*=10 (FIG. 15B), L*=30 (FIG. 15C), L*=50 (FIG. 15D), L*=80 (FIG. 15E), and L*=90 (FIG. 15F). As the semitransparent black layer 460 was printed using the CYMK color model, individual dots of cyan, magenta, and yellow can be seen over which black dots were printed. The CYMK color model was set with C at 55°. As can be seen in FIGS. 15E and 15F, the size of the individual ink dots was measured. The ink dots were oval in shape having a width of approximately 48 μm and a length of approximately 74 μm. Advantageously, using inkjet printing, the size of the ink dots can be varied depending on the inkjet nozzles used. Further, the viscosity of the ink can be controlled by increasing the proportion or changing the type of the pigment vehicle.

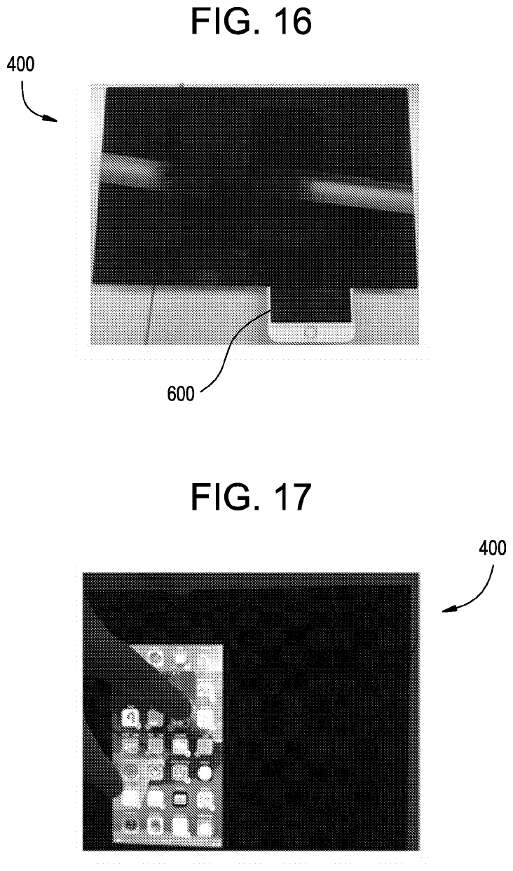

FIGS. 16 and 17 depict a deadfront article 400 covering a smartphone 600. The deadfront article 400 in these figures is at L*<10 with a transmittance of 5%. As can be seen in FIG. 16, the deadfront article 400 completely obscures the portion of the smartphone 600 covered by the deadfront article 400. When the display of the smartphone 600 is activated as shown in FIG. 17, the display can be seen through the deadfront article 400, while the non-display regions (e.g., white border) continue to be obscured. In an embodiment, the deadfront article 400 is used with a super bright display, such as an OLED display. Additionally, where the display has a brightness setting, the brightness setting is set to its maximum brightness in certain embodiments.

Advantageously, using the CMYK color model to create a deadfront article 400 having a semitransparent black layer 460 printed on substrate 450 allows for greater control of the reflectance and transmittance properties of the deadfront article 400. In particular, the semitransparent black layer thickness (generally from 1 μm to 5 μm) and printing density of the black ink (K ink, composite black, or rich black) can be used to control the amount of light that is transmitted through the deadfront. In particular, the CMYK printed semitransparent black layer allows for more linear control of the percent transmittance by varying the K-value or L* level. Furthermore, by using the CMYK color model to achieve black, the deadfront can be tailored to achieve low reflection, controllable transmission, and neutral black to hide a display screen when the screen is inactive. Further still, using inkjet printing technology, it is possible to make continuous and uniform coatings, and as compared to other printing methods such as screen printing, the resolution achieved using inkjet printing is much higher.

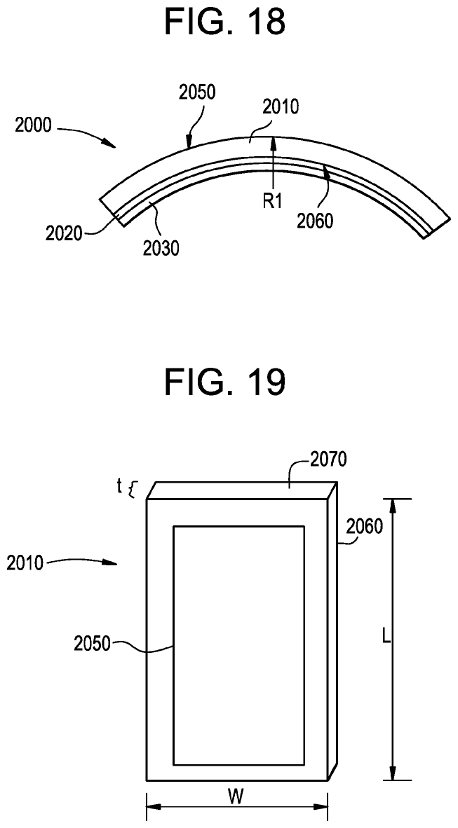

Referring to FIGS. 18-22, various sizes, shapes, curvatures, glass materials, etc. for a glass-based deadfront article along with various processes for forming a curved glass-based deadfront article are shown and described. It should be understood, that while FIGS. 18-22 are described in the context of a simplified curved deadfront article 2000 for ease of explanation, deadfront article 2000 may be any of the deadfront embodiments discussed herein.

As shown in FIG. 18, in one or more embodiments, deadfront article 2000 includes a curved outer glass substrate 2010 having at least a first radius of curvature, R1, and in various embodiments, curved outer glass substrate 2010 is a complex curved sheet of glass material having at least one additional radius of curvature. In various embodiments, R1 is in a range from about 60 mm to about 1500 mm.

Curved deadfront article 2000 includes a deadfront colored layer 2020 (e.g., the ink/pigment layer(s), as discussed above) located along an inner, major surface of curved outer glass substrate 2010. In general, deadfront colored layer 2020 is printed, colored, shaped, etc. to provide a wood-grain design, a leather-grain design, a fabric design, a brushed metal design, a graphic design, a solid color and/or a logo. Curved deadfront 2000 also may include any of the additional layers 2030 (e.g., high optical density layers, light guide layers, reflector layers, display module(s), display stack layers, light sources, etc.) as discussed above or that otherwise may be associated with a display or vehicle interior system as discussed herein.

As will be discussed in more detail below, in various embodiments, curved deadfront 2000 including glass substrate 2010 and colored layer 2020 may be cold-formed together to a curved shape, as shown in FIG. 18. In some embodiments, curved deadfront 2000 including glass substrate 2010, colored layer 2020 and additional layers 2030 may be cold-formed together to a curved shape, such as that shown in FIG. 6. In other embodiments, glass substrate 2010 may be formed to a curved shape, and then layers 2020 and 2030 are applied following curve formation.

Referring to FIG. 19, outer glass substrate 2010 is shown prior to being formed to the curved shape shown in FIG. 19. In general, Applicant believes that the articles and processes discussed herein provide high quality deadfront structures utilizing glass of sizes, shapes, compositions, strengths, etc. not previously provided.

As shown in FIG. 19, outer glass substrate 2010 includes a first major surface 2050 and a second major surface 2060 opposite first major surface 2050. An edge surface or minor surface 2070 connects the first major surface 2050 and the second major surface 2060. Outer glass substrate 2010 has a thickness (t) that is substantially constant and is defined as a distance between the first major surface 2050 and the second major surface 2060. In some embodiments, the thickness (t) as used herein refers to the maximum thickness of the outer glass substrate 2010. Outer glass substrate 2010 includes a width (W) defined as a first maximum dimension of one of the first or second major surfaces orthogonal to the thickness (t), and outer glass substrate 2010 also includes a length (L) defined as a second maximum dimension of one of the first or second surfaces orthogonal to both the thickness and the width. In other embodiments, the dimensions discussed herein are average dimensions.

In one or more embodiments, outer glass substrate 2010 has a thickness (t) that is in a range from 0.05 mm to 2 mm. In various embodiments, outer glass substrate 2010 has a thickness (t) that is about 1.5 mm or less. For example, the thickness may be in a range from about 0.1 mm to about 1.5 mm, from about 0.15 mm to about 1.5 mm, from about 0.2 mm to about 1.5 mm, from about 0.25 mm to about 1.5 mm, from about 0.3 mm to about 1.5 mm, from about 0.35 mm to about 1.5 mm, from about 0.4 mm to about 1.5 mm, from about 0.45 mm to about 1.5 mm, from about 0.5 mm to about 1.5 mm, from about 0.55 mm to about 1.5 mm, from about 0.6 mm to about 1.5 mm, from about 0.65 mm to about 1.5 mm, from about 0.7 mm to about 1.5 mm, from about 0.1 mm to about 1.4 mm, from about 0.1 mm to about 1.3 mm, from about 0.1 mm to about 1.2 mm, from about 0.1 mm to about 1.1 mm, from about 0.1 mm to about 1.05 mm, from about 0.1 mm to about 1 mm, from about 0.1 mm to about 0.95 mm, from about 0.1 mm to about 0.9 mm, from about 0.1 mm to about 0.85 mm, from about 0.1 mm to about 0.8 mm, from about 0.1 mm to about 0.75 mm, from about 0.1 mm to about 0.7 mm, from about 0.1 mm to about 0.65 mm, from about 0.1 mm to about 0.6 mm, from about 0.1 mm to about 0.55 mm, from about 0.1 mm to about 0.5 mm, from about 0.1 mm to about 0.4 mm, or from about 0.3 mm to about 0.7 mm.

In one or more embodiments, outer glass substrate 2010 has a width (W) in a range from about 5 cm to about 250 cm, from about 10 cm to about 250 cm, from about 15 cm to about 250 cm, from about 20 cm to about 250 cm, from about 25 cm to about 250 cm, from about 30 cm to about 250 cm, from about 35 cm to about 250 cm, from about 40 cm to about 250 cm, from about 45 cm to about 250 cm, from about 50 cm to about 250 cm, from about 55 cm to about 250 cm, from about 60 cm to about 250 cm, from about 65 cm to about 250 cm, from about 70 cm to about 250 cm, from about 75 cm to about 250 cm, from about 80 cm to about 250 cm, from about 85 cm to about 250 cm, from about 90 cm to about 250 cm, from about 95 cm to about 250 cm, from about 100 cm to about 250 cm, from about 110 cm to about 250 cm, from about 120 cm to about 250 cm, from about 130 cm to about 250 cm, from about 140 cm to about 250 cm, from about 150 cm to about 250 cm, from about 5 cm to about 240 cm, from about 5 cm to about 230 cm, from about 5 cm to about 220 cm, from about 5 cm to about 210 cm, from about 5 cm to about 200 cm, from about 5 cm to about 190 cm, from about 5 cm to about 180 cm, from about 5 cm to about 170 cm, from about 5 cm to about 160 cm, from about 5 cm to about 150 cm, from about 5 cm to about 140 cm, from about 5 cm to about 130 cm, from about 5 cm to about 120 cm, from about 5 cm to about 110 cm, from about 5 cm to about 100 cm, from about 5 cm to about 90 cm, from about 5 cm to about 80 cm, or from about 5 cm to about 75 cm.

In one or more embodiments, outer glass substrate 2010 has a length (L) in a range from about 5 cm to about 250 cm, from about 10 cm to about 250 cm, from about 15 cm to about 250 cm, from about 20 cm to about 250 cm, from about 25 cm to about 250 cm, from about 30 cm to about 250 cm, from about 35 cm to about 250 cm, from about 40 cm to about 250 cm, from about 45 cm to about 250 cm, from about 50 cm to about 250 cm, from about 55 cm to about 250 cm, from about 60 cm to about 250 cm, from about 65 cm to about 250 cm, from about 70 cm to about 250 cm, from about 75 cm to about 250 cm, from about 80 cm to about 250 cm, from about 85 cm to about 250 cm, from about 90 cm to about 250 cm, from about 95 cm to about 250 cm, from about 100 cm to about 250 cm, from about 110 cm to about 250 cm, from about 120 cm to about 250 cm, from about 130 cm to about 250 cm, from about 140 cm to about 250 cm, from about 150 cm to about 250 cm, from about 5 cm to about 240 cm, from about 5 cm to about 230 cm, from about 5 cm to about 220 cm, from about 5 cm to about 210 cm, from about 5 cm to about 200 cm, from about 5 cm to about 190 cm, from about 5 cm to about 180 cm, from about 5 cm to about 170 cm, from about 5 cm to about 160 cm, from about 5 cm to about 150 cm, from about 5 cm to about 140 cm, from about 5 cm to about 130 cm, from about 5 cm to about 120 cm, from about 5 cm to about 110 cm, from about 5 cm to about 100 cm, from about 5 cm to about 90 cm, from about 5 cm to about 80 cm, or from about 5 cm to about 75 cm.

As shown in FIG. 18, outer glass substrate 2010 is shaped to a curved shaping having at least one radius of curvature, shown as R1. In various embodiments, outer glass substrate 2010 may be shaped to the curved shape via any suitable process, including cold-forming and hot-forming.

In specific embodiments, outer glass substrate 2010 is shaped to the curved shape shown in FIG. 18, either alone, or following attachment of layers 2020 and 2030, via a cold-forming process. As used herein, the terms “cold-bent,” “cold-bending,” “cold-formed” or “cold-forming” refers to curving the glass deadfront at a cold-form temperature which is less than the softening point of the glass (as described herein). A feature of a cold-formed glass substrate is an asymmetric surface compressive between the first major surface 2050 and the second major surface 2060. In some embodiments, prior to the cold-forming process or being cold-formed, the respective compressive stresses in the first major surface 2050 and the second major surface 2060 are substantially equal.

In some such embodiments in which outer glass substrate 2010 is unstrengthened, the first major surface 2050 and the second major surface 2060 exhibit no appreciable compressive stress, prior to cold-forming. In some such embodiments in which outer glass substrate 2010 is strengthened (as described herein), the first major surface 2050 and the second major surface 2060 exhibit substantially equal compressive stress with respect to one another, prior to cold-forming. In one or more embodiments, after cold-forming (shown, for example, in FIG. 18) the compressive stress on the second major surface 2060 (e.g., the concave surface following bending) increases (i.e., the compressive stress on the second major surface 2050 is greater after cold-forming than before cold-forming).

Without being bound by theory, the cold-forming process increases the compressive stress of the glass article being shaped to compensate for tensile stresses imparted during bending and/or forming operations. In one or more embodiments, the cold-forming process causes the second major surface 2060 to experience compressive stresses, while the first major surface 2050 (e.g., the convex surface following bending) experiences tensile stresses. The tensile stress experienced by surface 2050 following bending results in a net decrease in surface compressive stress, such that the compressive stress in surface 2050 of a strengthened glass sheet following bending is less than the compressive stress in surface 2050 when the glass sheet is flat.

Further, when a strengthened glass sheet is utilized for outer glass substrate 2010, the first major surface and the second major surface (2050,2060) are already under compressive stress, and thus first major surface 2050 can experience greater tensile stress during bending without risking fracture. This allows for the strengthened embodiments of outer glass substrate 2010 to conform to more tightly curved surfaces (e.g., shaped to have smaller R1 values).

In various embodiments, the thickness of outer glass substrate 2010 is tailored to allow outer glass substrate 2010 to be more flexible to achieve the desired radius of curvature. Moreover, a thinner outer glass substrate 2010 may deform more readily, which could potentially compensate for shape mismatches and gaps that may be created by the shape of a support or frame (as discussed below). In one or more embodiments, a thin and strengthened outer glass substrate 2010 exhibits greater flexibility especially during cold-forming. The greater flexibility of the glass articles discussed herein may allow for consistent bend formation without heating.

In various embodiments, outer glass substrate 2010 (and consequently deadfront 2000) may have a compound curve including a major radius and a cross curvature. A complexly curved cold-formed outer glass substrate 2010 may have a distinct radius of curvature in two independent directions. According to one or more embodiments, the complexly curved cold-formed outer glass substrate 2010 may thus be characterized as having “cross curvature,” where the cold-formed outer glass substrate 2010 is curved along an axis (i.e., a first axis) that is parallel to a given dimension and also curved along an axis (i.e., a second axis) that is perpendicular to the same dimension. The curvature of the cold-formed outer glass substrate 2010 can be even more complex when a significant minimum radius is combined with a significant cross curvature, and/or depth of bend.

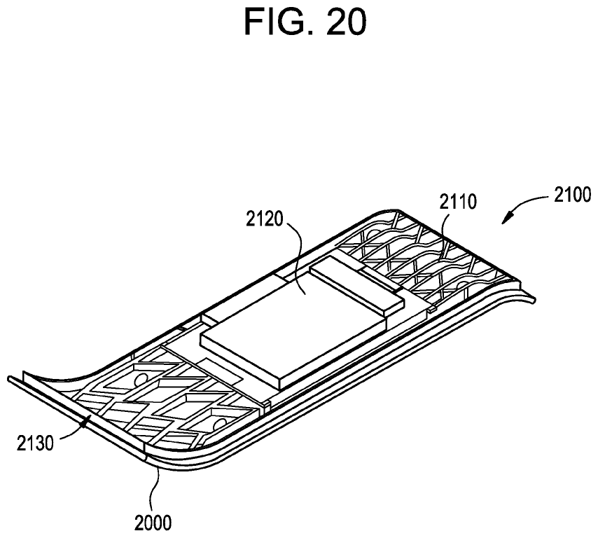

Referring to FIG. 20, display assembly 2100 is shown according to an exemplary embodiment. In the embodiment shown, display assembly 2100 includes frame 2110 supporting (either directly or indirectly) both a light source, shown as a display module 2120, and deadfront structure 2000. As shown in FIG. 20, deadfront structure 2000 and display module 2120 are coupled to frame 2110, and display module 2120 is positioned to allow a user to view light, images, etc. generated by display module 2120 through deadfront structure 2000. In various embodiments, frame 2110 may be formed from a variety of materials such as plastic (PC/ABS, etc.), metals (Al-alloys, Mg-alloys, Fe-alloys, etc.). Various processes such as casting, machining, stamping, injection molding, etc. may be utilized to form the curved shape of frame 2110. While FIG. 20 shows a light source in the form of a display module, it should be understood that display assembly 2100 may include any of the light sources discussed herein for producing graphics, icons, images, displays, etc. through any of the dead front embodiments discussed herein. Further, while frame 2110 is shown as a frame associated with a display assembly, frame 2110 may be any support or frame structure associated with a vehicle interior system.

In various embodiments, the systems and methods described herein allow for formation of deadfront structure 2000 to conform to a wide variety of curved shapes that frame 2110 may have. As shown in FIG. 20, frame 2110 has a support surface 2130 that has a curved shape, and deadfront structure 2000 is shaped to match the curved shape of support surface 2130. As will be understood, deadfront structure 2000 may be shaped into a wide variety of shapes to conform to a desired frame shape of a display assembly 2100, which in turn may be shaped to fit the shape of a portion of a vehicle interior system, as discussed herein.

In one or more embodiments, deadfront structure 2000 (and specifically outer glass substrate 2010) is shaped to have a first radius of curvature, R1, of about 60 mm or greater. For example, R1 may be in a range from about 60 mm to about 1500 mm, from about 70 mm to about 1500 mm, from about 80 mm to about 1500 mm, from about 90 mm to about 1500 mm, from about 100 mm to about 1500 mm, from about 120 mm to about 1500 mm, from about 140 mm to about 1500 mm, from about 150 mm to about 1500 mm, from about 160 mm to about 1500 mm, from about 180 mm to about 1500 mm, from about 200 mm to about 1500 mm, from about 220 mm to about 1500 mm, from about 240 mm to about 1500 mm, from about 250 mm to about 1500 mm, from about 260 mm to about 1500 mm, from about 270 mm to about 1500 mm, from about 280 mm to about 1500 mm, from about 290 mm to about 1500 mm, from about 300 mm to about 1500 mm, from about 350 mm to about 1500 mm, from about 400 mm to about 1500 mm, from about 450 mm to about 1500 mm, from about 500 mm to about 1500 mm, from about 550 mm to about 1500 mm, from about 600 mm to about 1500 mm, from about 650 mm to about 1500 mm, from about 700 mm to about 1500 mm, from about 750 mm to about 1500 mm, from about 800 mm to about 1500 mm, from about 900 mm to about 1500 mm, from about 9500 mm to about 1500 mm, from about 1000 mm to about 1500 mm, from about 1250 mm to about 1500 mm, from about 60 mm to about 1400 mm, from about 60 mm to about 1300 mm, from about 60 mm to about 1200 mm, from about 60 mm to about 1100 mm, from about 60 mm to about 1000 mm, from about 60 mm to about 950 mm, from about 60 mm to about 900 mm, from about 60 mm to about 850 mm, from about 60 mm to about 800 mm, from about 60 mm to about 750 mm, from about 60 mm to about 700 mm, from about 60 mm to about 650 mm, from about 60 mm to about 600 mm, from about 60 mm to about 550 mm, from about 60 mm to about 500 mm, from about 60 mm to about 450 mm, from about 60 mm to about 400 mm, from about 60 mm to about 350 mm, from about 60 mm to about 300 mm, or from about 60 mm to about 250 mm.

In one or more embodiments, support surface 2130 has a second radius of curvature of about 60 mm or greater. For example, the second radius of curvature of support surface 2130 may be in a range from about 60 mm to about 1500 mm, from about 70 mm to about 1500 mm, from about 80 mm to about 1500 mm, from about 90 mm to about 1500 mm, from about 100 mm to about 1500 mm, from about 120 mm to about 1500 mm, from about 140 mm to about 1500 mm, from about 150 mm to about 1500 mm, from about 160 mm to about 1500 mm, from about 180 mm to about 1500 mm, from about 200 mm to about 1500 mm, from about 220 mm to about 1500 mm, from about 240 mm to about 1500 mm, from about 250 mm to about 1500 mm, from about 260 mm to about 1500 mm, from about 270 mm to about 1500 mm, from about 280 mm to about 1500 mm, from about 290 mm to about 1500 mm, from about 300 mm to about 1500 mm, from about 350 mm to about 1500 mm, from about 400 mm to about 1500 mm, from about 450 mm to about 1500 mm, from about 500 mm to about 1500 mm, from about 550 mm to about 1500 mm, from about 600 mm to about 1500 mm, from about 650 mm to about 1500 mm, from about 700 mm to about 1500 mm, from about 750 mm to about 1500 mm, from about 800 mm to about 1500 mm, from about 900 mm to about 1500 mm, from about 9500 mm to about 1500 mm, from about 1000 mm to about 1500 mm, from about 1250 mm to about 1500 mm, from about 60 mm to about 1400 mm, from about 60 mm to about 1300 mm, from about 60 mm to about 1200 mm, from about 60 mm to about 1100 mm, from about 60 mm to about 1000 mm, from about 60 mm to about 950 mm, from about 60 mm to about 900 mm, from about 60 mm to about 850 mm, from about 60 mm to about 800 mm, from about 60 mm to about 750 mm, from about 60 mm to about 700 mm, from about 60 mm to about 650 mm, from about 60 mm to about 600 mm, from about 60 mm to about 550 mm, from about 60 mm to about 500 mm, from about 60 mm to about 450 mm, from about 60 mm to about 400 mm, from about 60 mm to about 350 mm, from about 60 mm to about 300 mm, or from about 60 mm to about 250 mm.

In one or more embodiments, deadfront structure 2000 is cold-formed to exhibit a first radius curvature, R1, that is within 10% (e.g., about 10% or less, about 9% or less, about 8% or less, about 7% or less, about 6% or less, or about 5% or less) of the second radius of curvature of support surface 2130 of frame 2110. For example, support surface 2130 of frame 2110 exhibits a radius of curvature of 1000 mm, deadfront structure 2000 is cold-formed to have a radius of curvature in a range from about 900 mm to about 1100 mm.

In one or more embodiments, first major surface 2050 and/or second major surface 2060 of glass substrate 2010 includes a functional coating layer as described herein. The functional coating layer may cover at least a portion of first major surface 2050 and/or second major surface 2060. Exemplary functional coatings include at least one of a glare reduction coating or surface, an anti-glare coating or surface, a scratch resistance coating, an anti-reflection coating, a half-mirror coating, or easy-to-clean coating.

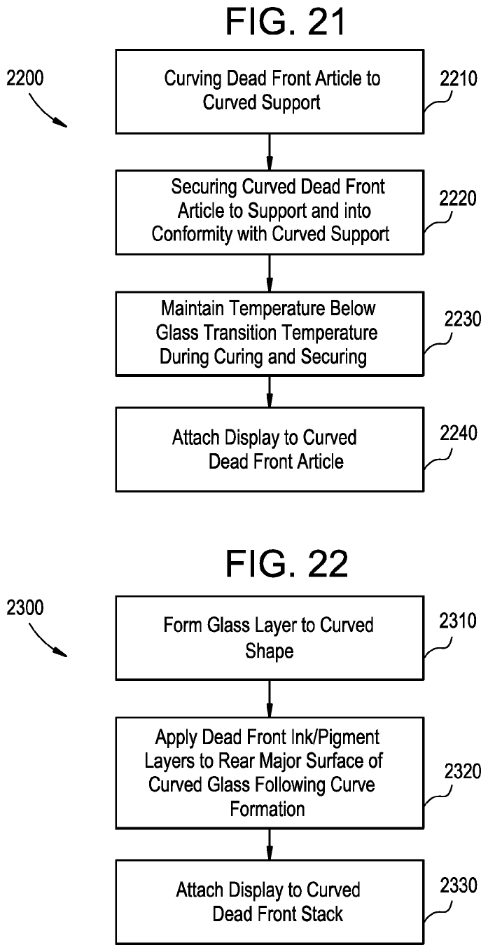

Referring to FIG. 21, a method 2200 for forming a display assembly that includes a cold-formed deadfront article, such as deadfront article 2000 is shown. At step 2210, the method includes curving a deadfront article, such as deadfront structure 2000, to a curved surface of a support. In general, the support may be a frame of a display, such as frame 2110, that defines a perimeter and curved shape of a vehicle display. In general, the frame includes a curved support surface, and one of the major surfaces 2050 and 2060 of deadfront article 2000 is placed into contact with the curved support surface.

At step 2220, the method includes securing the curved deadfront article to the support causing the deadfront article to bend into conformity (or conform) with the curved surface of the support. In this manner, a curved deadfront article 2000, as shown in FIG. 18, is formed from a generally flat deadfront article to a curved deadfront article. In this arrangement, curving the flat deadfront article forms a curved shape on the major surface facing the support, while also causing a corresponding (but complimentary) curve to form in the major surface opposite of the frame. Applicant believes that by bending the deadfront article directly on the curved frame, the need for a separate curved die or mold (typically needed in other glass bending processes) is eliminated. Further, Applicant believes that by shaping the deadfront directly to the curved frame, a wide range of curved radii may be achieved in a low complexity manufacturing process.

In some embodiments, the force applied in step 2210 and/or step 2220 may be air pressure applied via a vacuum fixture. In some other embodiments, the air pressure differential is formed by applying a vacuum to an airtight enclosure surrounding the frame and the deadfront article. In specific embodiments, the airtight enclosure is a flexible polymer shell, such as a plastic bag or pouch. In other embodiments, the air pressure differential is formed by generating increased air pressure around the deadfront article and the frame with an overpressure device, such as an autoclave. Applicant has further found that air pressure provides a consistent and highly uniform bending force (as compared to a contact-based bending method) which further leads to a robust manufacturing process. In various embodiments, the air pressure differential is between 0.5 and 1.5 atmospheres of pressure (atm), specifically between 0.7 and 1.1 atm, and more specifically is 0.8 to 1 atm.

At step 2230, the temperature of the deadfront article is maintained below the glass transition temperature of the material of the outer glass substrate during steps 2210 and 2220. As such, method 2200 is a cold-forming or cold-bending process. In particular embodiments, the temperature of the deadfront article is maintained below 500 degrees C., 400 degrees C., 300 degrees C., 200 degrees C. or 100 degrees C. In a particular embodiment, the deadfront structure is maintained at or below room temperature during bending. In a particular embodiment, the deadfront article is not actively heated via a heating element, furnace, oven, etc. during bending, as is the case when hot-forming glass to a curved shape.

As noted above, in addition to providing processing advantages such as eliminating expensive and/or slow heating steps, the cold-forming processes discussed herein are believed to generate curved deadfront article with a variety of properties that are believed to be superior to those achievable via hot-forming processes. For example, Applicant believes that, for at least some glass materials, heating during hot-forming processes decreases optical properties of curved glass substrates, and thus, the curved glass based deadfront articles formed utilizing the cold-bending processes/systems discussed herein provide for both curved glass shape along with improved optical qualities not believed achievable with hot-bending processes.

Further, many materials used for various coatings and layers (e.g., easy-to-clean coatings, anti-reflective coatings, etc.) are applied via deposition processes, such as sputtering processes, that are typically ill-suited for coating on to a curved surface. In addition, many coating materials, such as the deadfront ink/pigment materials, also are not able to survive the high temperatures associated with hot-bending processes. Thus, in particular embodiments discussed herein, layer 2020 is applied to outer glass substrate 2010 prior to cold-bending Thus, Applicant believes that the processes and systems discussed herein allow for bending of glass after one or more coating material has been applied to the glass, in contrast to typical hot-forming processes.

At step 2220, the curved deadfront article is attached or affixed to the curved support. In various embodiments, the attachment between the curved deadfront article and the curved support may be accomplished via an adhesive material. Such adhesives may include any suitable optically clear adhesive for bonding the deadfront article in place relative to the display assembly (e.g., to the frame of the display). In one example, the adhesive may include an optically clear adhesive available from 3M Corporation under the trade name 8215. The thickness of the adhesive may be in a range from about 200 μm to about 500 μm.

The adhesive material may be applied in a variety ways. In one embodiment, the adhesive is applied using an applicator gun and made uniform using a roller or a draw down die. In various embodiments, the adhesives discussed herein are structural adhesives. In particular embodiments, the structural adhesives may include an adhesive selected from one or more of the categories: (a) Toughened Epoxy (Masterbond EP21TDCHT-LO, 3M Scotch Weld Epoxy DP460 Off-white); (b) Flexible Epoxy (Masterbond EP21TDC-2LO, 3M Scotch Weld Epoxy 2216 B/A Gray); (c) Acrylic (LORD Adhesive 410/Accelerator 19 w/LORD AP 134 primer, LORD Adhesive 852/LORD Accelerator 25 GB, Loctite HF8000, Loctite AA4800); (d) Urethanes (3M Scotch Weld Urethane DP640 Brown); and (e) Silicones (Dow Corning 995). In some cases, structural glues available in sheet format (such as B-staged epoxy adhesives) may be utilized. Furthermore, pressure sensitive structural adhesives such as 3M VHB tapes may be utilized. In such embodiments, utilizing a pressure sensitive adhesive allows for the curved deadfront article to be bonded to the frame without the need for a curing step.

In one or more embodiments, the method includes step 2240 in which the curved deadfront is secured to a display. In one or more embodiments, the method may include securing the display to the deadfront article before step 2210 and curving both the display and the deadfront article in step 2210. In one or more embodiments, the method includes disposing or assembling the curved display in a vehicle interior system 100, 200, 300.

Referring to FIG. 22, method 2300 for forming a display utilizing a curved deadfront article is shown and described. In some embodiments, the glass substrate (e.g., outer glass substrate 2010) of a deadfront structure is formed to curved shape at step 2310. Shaping at step 2310 may be either cold-forming or hot-forming. At step 2320, the deadfront ink/pigment layer(s) (e.g., layer 2020) is applied to the glass substrate following shaping to provide a curved deadfront article. Next at step 2330, the curved deadfront article is attached to a frame, such as frame 2110 of display assembly 2100, or other frame that may be associated with a vehicle interior system.

Substrate Materials

The various glass substrate sof the deadfront structures discussed herein, such as outer glass substrate 2010, may be formed from any transparent material such as a polymer (e.g., PMMA, polycarbonate and the like) or glass. Suitable glass composition including soda lime glass, aluminosilicate glass, borosilicate glass, boroaluminosilicate glass, alkali-containing aluminosilicate glass, alkali-containing borosilicate glass, and alkali-containing boroaluminosilicate glass.

Unless otherwise specified, the glass compositions disclosed herein are described in mole percent (mol %) as analyzed on an oxide basis.

In one or more embodiments, the glass composition may include SiO₂ in an amount in a range from about 66 mol % to about 80 mol %, from about 67 mol % to about 80 mol %, from about 68 mol % to about 80 mol %, from about 69 mol % to about 80 mol %, from about 70 mol % to about 80 mol %, from about 72 mol % to about 80 mol %, from about 65 mol % to about 78 mol %, from about 65 mol % to about 76 mol %, from about 65 mol % to about 75 mol %, from about 65 mol % to about 74 mol %, from about 65 mol % to about 72 mol %, or from about 65 mol % to about 70 mol %, and all ranges and sub-ranges therebetween.

In one or more embodiments, the glass composition includes Al₂O₃ in an amount greater than about 4 mol %, or greater than about 5 mol %. In one or more embodiments, the glass composition includes Al₂O₃ in a range from greater than about 7 mol % to about 15 mol %, from greater than about 7 mol % to about 14 mol %, from about 7 mol % to about 13 mol %, from about 4 mol % to about 12 mol %, from about 7 mol % to about 11 mol %, from about 8 mol % to about 15 mol %, from 9 mol % to about 15 mol %, from about 9 mol % to about 15 mol %, from about 10 mol % to about 15 mol %, from about 11 mol % to about 15 mol %, or from about 12 mol % to about 15 mol %, and all ranges and sub-ranges therebetween. In one or more embodiments, the upper limit of Al₂O₃ may be about 14 mol %, 14.2 mol %, 14.4 mol %, 14.6 mol %, or 14.8 mol %.

In one or more embodiments, glass layer(s) herein are described as an aluminosilicate glass article or including an aluminosilicate glass composition. In such embodiments, the glass composition or article formed therefrom includes SiO₂ and Al₂O₃ and is not a soda lime silicate glass. In this regard, the glass composition or article formed therefrom includes Al₂O₃ in an amount of about 2 mol % or greater, 2.25 mol % or greater, 2.5 mol % or greater, about 2.75 mol % or greater, about 3 mol % or greater.

In one or more embodiments, the glass composition comprises B₂O₃ (e.g., about 0.01 mol % or greater). In one or more embodiments, the glass composition comprises B₂O₃ in an amount in a range from about 0 mol % to about 5 mol %, from about 0 mol % to about 4 mol %, from about 0 mol % to about 3 mol %, from about 0 mol % to about 2 mol %, from about 0 mol % to about 1 mol %, from about 0 mol % to about 0.5 mol %, from about 0.1 mol % to about 5 mol %, from about 0.1 mol % to about 4 mol %, from about 0.1 mol % to about 3 mol %, from about 0.1 mol % to about 2 mol %, from about 0.1 mol % to about 1 mol %, from about 0.1 mol % to about 0.5 mol %, and all ranges and sub-ranges therebetween. In one or more embodiments, the glass composition is substantially free of B₂O₃.

As used herein, the phrase “substantially free” with respect to the components of the composition means that the component is not actively or intentionally added to the composition during initial batching, but may be present as an impurity in an amount less than about 0.001 mol %.

In one or more embodiments, the glass composition optionally comprises P₂O₅ (e.g., about 0.01 mol % or greater). In one or more embodiments, the glass composition comprises a non-zero amount of P₂O₅ up to and including 2 mol %, 1.5 mol %, 1 mol %, or 0.5 mol %. In one or more embodiments, the glass composition is substantially free of P₂O₅.

In one or more embodiments, the glass composition may include a total amount of R₂O (which is the total amount of alkali metal oxide such as Li₂O, Na₂O, K2O, Rb₂O, and Cs₂O) that is greater than or equal to about 8 mol %, greater than or equal to about 10 mol %, or greater than or equal to about 12 mol %. In some embodiments, the glass composition includes a total amount of R₂O in a range from about 8 mol % to about 20 mol %, from about 8 mol % to about 18 mol %, from about 8 mol % to about 16 mol %, from about 8 mol % to about 14 mol %, from about 8 mol % to about 12 mol %, from about 9 mol % to about 20 mol %, from about 10 mol % to about 20 mol %, from about 11 mol % to about 20 mol %, from about 12 mol % to about 20 mol %, from about 13 mol % to about 20 mol %, from about 10 mol % to about 14 mol %, or from 11 mol % to about 13 mol %, and all ranges and sub-ranges therebetween. In one or more embodiments, the glass composition may be substantially free of Rb₂O, Cs₂O or both Rb₂O and Cs₂O. In one or more embodiments, the R₂O may include the total amount of Li₂O, Na₂O and K₂O only. In one or more embodiments, the glass composition may comprise at least one alkali metal oxide selected from Li₂O, Na₂O and K₂O, wherein the alkali metal oxide is present in an amount greater than about 8 mol % or greater.

In one or more embodiments, the glass composition comprises Na₂O in an amount greater than or equal to about 8 mol %, greater than or equal to about 10 mol %, or greater than or equal to about 12 mol %. In one or more embodiments, the composition includes Na₂O in a range from about from about 8 mol % to about 20 mol %, from about 8 mol % to about 18 mol %, from about 8 mol % to about 16 mol %, from about 8 mol % to about 14 mol %, from about 8 mol % to about 12 mol %, from about 9 mol % to about 20 mol %, from about 10 mol % to about 20 mol %, from about 11 mol % to about 20 mol %, from about 12 mol % to about 20 mol %, from about 13 mol % to about 20 mol %, from about 10 mol % to about 14 mol %, or from 11 mol % to about 16 mol %, and all ranges and sub-ranges therebetween.

In one or more embodiments, the glass composition includes less than about 4 mol % K₂O, less than about 3 mol % K₂O, or less than about 1 mol % K₂O. In some instances, the glass composition may include K₂O in an amount in a range from about 0 mol % to about 4 mol %, from about 0 mol % to about 3.5 mol %, from about 0 mol % to about 3 mol %, from about 0 mol % to about 2.5 mol %, from about 0 mol % to about 2 mol %, from about 0 mol % to about 1.5 mol %, from about 0 mol % to about 1 mol %, from about 0 mol % to about 0.5 mol %, from about 0 mol % to about 0.2 mol %, from about 0 mol % to about 0.1 mol %, from about 0.5 mol % to about 4 mol %, from about 0.5 mol % to about 3.5 mol %, from about 0.5 mol % to about 3 mol %, from about 0.5 mol % to about 2.5 mol %, from about 0.5 mol % to about 2 mol %, from about 0.5 mol % to about 1.5 mol %, or from about 0.5 mol % to about 1 mol %, and all ranges and sub-ranges therebetween. In one or more embodiments, the glass composition may be substantially free of K₂O.

In one or more embodiments, the glass composition is substantially free of Li₂O.

In one or more embodiments, the amount of Na₂O in the composition may be greater than the amount of Li₂O. In some instances, the amount of Na₂O may be greater than the combined amount of Li₂O and K2O. In one or more alternative embodiments, the amount of Li₂O in the composition may be greater than the amount of Na₂O or the combined amount of Na₂O and K₂O.

In one or more embodiments, the glass composition may include a total amount of RO (which is the total amount of alkaline earth metal oxide such as CaO, MgO, BaO, ZnO and SrO) in a range from about 0 mol % to about 2 mol %. In some embodiments, the glass composition includes a non-zero amount of RO up to about 2 mol %. In one or more embodiments, the glass composition comprises RO in an amount from about 0 mol % to about 1.8 mol %, from about 0 mol % to about 1.6 mol %, from about 0 mol % to about 1.5 mol %, from about 0 mol % to about 1.4 mol %, from about 0 mol % to about 1.2 mol %, from about 0 mol % to about 1 mol %, from about 0 mol % to about 0.8 mol %, from about 0 mol % to about 0.5 mol %, and all ranges and sub-ranges therebetween.

In one or more embodiments, the glass composition includes CaO in an amount less than about 1 mol %, less than about 0.8 mol %, or less than about 0.5 mol %. In one or more embodiments, the glass composition is substantially free of CaO.

In some embodiments, the glass composition comprises MgO in an amount from about 0 mol % to about 7 mol %, from about 0 mol % to about 6 mol %, from about 0 mol % to about 5 mol %, from about 0 mol % to about 4 mol %, from about 0.1 mol % to about 7 mol %, from about 0.1 mol % to about 6 mol %, from about 0.1 mol % to about 5 mol %, from about 0.1 mol % to about 4 mol %, from about 1 mol % to about 7 mol %, from about 2 mol % to about 6 mol %, or from about 3 mol % to about 6 mol %, and all ranges and sub-ranges therebetween.

In one or more embodiments, the glass composition comprises ZrO₂ in an amount equal to or less than about 0.2 mol %, less than about 0.18 mol %, less than about 0.16 mol %, less than about 0.15 mol %, less than about 0.14 mol %, less than about 0.12 mol %. In one or more embodiments, the glass composition comprises ZrO₂ in a range from about 0.01 mol % to about 0.2 mol %, from about 0.01 mol % to about 0.18 mol %, from about 0.01 mol % to about 0.16 mol %, from about 0.01 mol % to about 0.15 mol %, from about 0.01 mol % to about 0.14 mol %, from about 0.01 mol % to about 0.12 mol %, or from about 0.01 mol % to about 0.10 mol %, and all ranges and sub-ranges therebetween.

In one or more embodiments, the glass composition comprises SnO₂ in an amount equal to or less than about 0.2 mol %, less than about 0.18 mol %, less than about 0.16 mol %, less than about 0.15 mol %, less than about 0.14 mol %, less than about 0.12 mol %. In one or more embodiments, the glass composition comprises SnO₂ in a range from about 0.01 mol % to about 0.2 mol %, from about 0.01 mol % to about 0.18 mol %, from about 0.01 mol % to about 0.16 mol %, from about 0.01 mol % to about 0.15 mol %, from about 0.01 mol % to about 0.14 mol %, from about 0.01 mol % to about 0.12 mol %, or from about 0.01 mol % to about 0.10 mol %, and all ranges and sub-ranges therebetween.

In one or more embodiments, the glass composition may include an oxide that imparts a color or tint to the glass articles. In some embodiments, the glass composition includes an oxide that prevents discoloration of the glass article when the glass article is exposed to ultraviolet radiation. Examples of such oxides include, without limitation oxides of. Ti, V, Cr, Mn, Fe, Co, Ni, Cu, Ce, W, and Mo.

In one or more embodiments, the glass composition includes Fe expressed as Fe₂O₃, wherein Fe is present in an amount up to (and including) about 1 mol %. In some embodiments, the glass composition is substantially free of Fe. In one or more embodiments, the glass composition comprises Fe₂O₃ in an amount equal to or less than about 0.2 mol %, less than about 0.18 mol %, less than about 0.16 mol %, less than about 0.15 mol %, less than about 0.14 mol %, less than about 0.12 mol %. In one or more embodiments, the glass composition comprises Fe₂O₃ in a range from about 0.01 mol % to about 0.2 mol %, from about 0.01 mol % to about 0.18 mol %, from about 0.01 mol % to about 0.16 mol %, from about 0.01 mol % to about 0.15 mol %, from about 0.01 mol % to about 0.14 mol %, from about 0.01 mol % to about 0.12 mol %, or from about 0.01 mol % to about 0.10 mol %, and all ranges and sub-ranges therebetween.

Where the glass composition includes TiO₂, TiO₂ may be present in an amount of about 5 mol % or less, about 2.5 mol % or less, about 2 mol % or less or about 1 mol % or less. In one or more embodiments, the glass composition may be substantially free of TiO₂.

An exemplary glass composition includes SiO₂ in an amount in a range from about 65 mol % to about 75 mol %, Al₂O₃ in an amount in a range from about 8 mol % to about 14 mol %, Na₂O in an amount in a range from about 12 mol % to about 17 mol %, K₂O in an amount in a range of about 0 mol % to about 0.2 mol %, and MgO in an amount in a range from about 1.5 mol % to about 6 mol %. Optionally, SnO₂ may be included in the amounts otherwise disclosed herein.

Strengthened Substrates

In one or more embodiments, the substrates that include a glass material (such as outer glass substrate 2010 or other glass substrates) of any of the deadfront article embodiments discussed herein. In one or more embodiments, such glass substrates may be strengthened. In one or more embodiments, the glass substrates used to form the deadfront articles discussed herein may be strengthened to include compressive stress that extends from a surface to a depth of compression (DOC). The compressive stress regions are balanced by a central portion exhibiting a tensile stress. At the DOC, the stress crosses from a positive (compressive) stress to a negative (tensile) stress.

In one or more embodiments, the glass substrates used to form the deadfront articles discussed herein may be strengthened mechanically by utilizing a mismatch of the coefficient of thermal expansion between portions of the glass to create a compressive stress region and a central region exhibiting a tensile stress. In some embodiments, the glass substrates may be strengthened thermally by heating the glass to a temperature above the glass transition point and then rapidly quenching.

In one or more embodiments, the glass substrates used to form the deadfront articles discussed herein may be chemically strengthening by ion exchange. In the ion exchange process, ions at or near the surface of the glass substrate are replaced by—or exchanged with—larger ions having the same valence or oxidation state. In those embodiments in which the glass substrate comprises an alkali aluminosilicate glass, ions in the surface layer of the article and the larger ions are monovalent alkali metal cations, such as Li⁺, Na⁺, Rb⁺, and Cs⁺. Alternatively, monovalent cations in the surface layer may be replaced with monovalent cations other than alkali metal cations, such as Ag⁺ or the like. In such embodiments, the monovalent ions (or cations) exchanged into the glass substrate generate a stress.

Ion exchange processes are typically carried out by immersing a glass substrate in a molten salt bath (or two or more molten salt baths) containing the larger ions to be exchanged with the smaller ions in the glass substrate. It should be noted that aqueous salt baths may also be utilized. In addition, the composition of the bath(s) may include more than one type of larger ion (e.g., Na+ and K+) or a single larger ion. It will be appreciated by those skilled in the art that parameters for the ion exchange process, including, but not limited to, bath composition and temperature, immersion time, the number of immersions of the glass substrate in a salt bath (or baths), use of multiple salt baths, additional steps such as annealing, washing, and the like, are generally determined by the composition of the glass layer(s) of a deadfront structure (including the structure of the article and any crystalline phases present) and the desired DOC and CS of the glass layer(s) of a deadfront structure that results from strengthening.

Exemplary molten bath composition may include nitrates, sulfates, and chlorides of the larger alkali metal ion. Typical nitrates include KNO₃, NaNO₃, LiNO₃, NaSO₄ and combinations thereof. The temperature of the molten salt bath typically is in a range from about 380° C. up to about 450° C., while immersion times range from about 15 minutes up to about 100 hours depending on the glass thickness, bath temperature and glass (or monovalent ion) diffusivity. However, temperatures and immersion times different from those described above may also be used.

In one or more embodiments, the glass substrates used to form the deadfront articles may be immersed in a molten salt bath of 100% NaNO₃, 100% KNO₃, or a combination of NaNO₃ and KNO₃ having a temperature from about 370° C. to about 480° C. In some embodiments, the glass layer(s) of a deadfront structure may be immersed in a molten mixed salt bath including from about 5% to about 90% KNO₃ and from about 10% to about 95% NaNO₃. In one or more embodiments, the glass substrate may be immersed in a second bath, after immersion in a first bath. The first and second baths may have different compositions and/or temperatures from one another. The immersion times in the first and second baths may vary. For example, immersion in the first bath may be longer than the immersion in the second bath.

In one or more embodiments, the glass substrates used to form the deadfront articles may be immersed in a molten, mixed salt bath including NaNO₃ and KNO₃ (e.g., 49%/51%, 50%/50%, 51%/49%) having a temperature less than about 420° C. (e.g., about 400° C. or about 380° C.). for less than about 5 hours, or even about 4 hours or less.

Ion exchange conditions can be tailored to provide a “spike” or to increase the slope of the stress profile at or near the surface of the resulting glass layer(s) of a deadfront structure. The spike may result in a greater surface CS value. This spike can be achieved by single bath or multiple baths, with the bath(s) having a single composition or mixed composition, due to the unique properties of the glass compositions used in the glass layer(s) of a deadfront structure described herein.

In one or more embodiments, where more than one monovalent ion is exchanged into the glass substrates used to form the deadfront articles, the different monovalent ions may exchange to different depths within the glass substrate (and generate different magnitudes stresses within the glass substrate at different depths). The resulting relative depths of the stress-generating ions can be determined and cause different characteristics of the stress profile.

CS is measured using those means known in the art, such as by surface stress meter (FSM) using commercially available instruments such as the FSM-6000, manufactured by Orihara Industrial Co., Ltd. (Japan). Surface stress measurements rely upon the accurate measurement of the stress optical coefficient (SOC), which is related to the birefringence of the glass. SOC in turn is measured by those methods that are known in the art, such as fiber and four point bend methods, both of which are described in ASTM standard C770-98 (2013), entitled “Standard Test Method for Measurement of Glass Stress-Optical Coefficient,” the contents of which are incorporated herein by reference in their entirety, and a bulk cylinder method. As used herein CS may be the “maximum compressive stress” which is the highest compressive stress value measured within the compressive stress layer. In some embodiments, the maximum compressive stress is located at the surface of the glass substrate. In other embodiments, the maximum compressive stress may occur at a depth below the surface, giving the compressive profile the appearance of a “buried peak.”

DOC may be measured by FSM or by a scattered light polariscope (SCALP) (such as the SCALP-04 scattered light polariscope available from Glasstress Ltd., located in Tallinn Estonia), depending on the strengthening method and conditions. When the glass substrate is chemically strengthened by an ion exchange treatment, FSM or SCALP may be used depending on which ion is exchanged into the glass substrate. Where the stress in the glass substrate is generated by exchanging potassium ions into the glass substrate, FSM is used to measure DOC. Where the stress is generated by exchanging sodium ions into the glass substrate, SCALP is used to measure DOC. Where the stress in the glass substrate is generated by exchanging both potassium and sodium ions into the glass, the DOC is measured by SCALP, since it is believed the exchange depth of sodium indicates the DOC and the exchange depth of potassium ions indicates a change in the magnitude of the compressive stress (but not the change in stress from compressive to tensile); the exchange depth of potassium ions in such glass substrates is measured by FSM. Central tension or CT is the maximum tensile stress and is measured by SCALP.

In one or more embodiments, the glass substrates used to form the layer(s) of the deadfront structures maybe strengthened to exhibit a DOC that is described a fraction of the thickness t of the glass substrate (as described herein). For example, in one or more embodiments, the DOC may be equal to or greater than about 0.05 t, equal to or greater than about 0.1 t, equal to or greater than about 0.11 t, equal to or greater than about 0.12 t, equal to or greater than about 0.13 t, equal to or greater than about 0.14 t, equal to or greater than about 0.15 t, equal to or greater than about 0.16 t, equal to or greater than about 0.17 t, equal to or greater than about 0.18 t, equal to or greater than about 0.19 t, equal to or greater than about 0.2 t, equal to or greater than about 0.21 t. In some embodiments, The DOC may be in a range from about 0.08 t to about 0.25 t, from about 0.09 t to about 0.25 t, from about 0.18 t to about 0.25 t, from about 0.11 t to about 0.25 t, from about 0.12 t to about 0.25 t, from about 0.13 t to about 0.25 t, from about 0.14 t to about 0.25 t, from about 0.15 t to about 0.25 t, from about 0.08 t to about 0.24 t, from about 0.08 t to about 0.23 t, from about 0.08 t to about 0.22 t, from about 0.08 t to about 0.21 t, from about 0.08 t to about 0.2 t, from about 0.08 t to about 0.19 t, from about 0.08 t to about 0.18 t, from about 0.08 t to about 0.17 t, from about 0.08 t to about 0.16 t, or from about 0.08 t to about 0.15 t. In some instances, the DOC may be about 20 μm or less. In one or more embodiments, the DOC may be about 40 μm or greater (e.g., from about 40 μm to about 300 μm, from about 50 μm to about 300 μm, from about 60 μm to about 300 μm, from about 70 μm to about 300 μm, from about 80 μm to about 300 μm, from about 90 μm to about 300 μm, from about 100 μm to about 300 μm, from about 110 μm to about 300 μm, from about 120 μm to about 300 μm, from about 140 μm to about 300 μm, from about 150 μm to about 300 μm, from about 40 μm to about 290 μm, from about 40 μm to about 280 μm, from about 40 μm to about 260 μm, from about 40 μm to about 250 μm, from about 40 μm to about 240 μm, from about 40 μm to about 230 μm, from about 40 μm to about 220 μm, from about 40 μm to about 210 μm, from about 40 μm to about 200 μm, from about 40 μm to about 180 μm, from about 40 μm to about 160 μm, from about 40 μm to about 150 μm, from about 40 μm to about 140 μm, from about 40 μm to about 130 μm, from about 40 μm to about 120 μm, from about 40 μm to about 110 μm, or from about 40 μm to about 100 μm.

In one or more embodiments, the glass substrates used to form the layer(s) of the deadfront structures may have a CS (which may be found at the surface or a depth within the glass substrate) of about 200 MPa or greater, 300 MPa or greater, 400 MPa or greater, about 500 MPa or greater, about 600 MPa or greater, about 700 MPa or greater, about 800 MPa or greater, about 900 MPa or greater, about 930 MPa or greater, about 1000 MPa or greater, or about 1050 MPa or greater.

In one or more embodiments, the glass substrates used to form the layer(s) of the deadfront structures may have a maximum tensile stress or central tension (CT) of about 20 MPa or greater, about 30 MPa or greater, about 40 MPa or greater, about 45 MPa or greater, about 50 MPa or greater, about 60 MPa or greater, about 70 MPa or greater, about 75 MPa or greater, about 80 MPa or greater, or about 85 MPa or greater. In some embodiments, the maximum tensile stress or central tension (CT) may be in a range from about 40 MPa to about 100 MPa.

Aspect (1) of the present disclosure pertains to a deadfront article for a display comprising: a substrate comprising: a first surface on a viewer-side of the glass layer; and a second surface opposite the first surface; and a semitransparent black layer disposed onto at least a first portion of the second surface of the substrate; wherein the semitransparent black layer is configured to obscure the display when the display is inactive and to allow viewing of the display when the display is active.

Aspect (2) of the present disclosure pertains to the deadfront article of Aspect (1), wherein the semitransparent black layer is printed onto the second surface of the glass layer with a printer using a CMYK color model.

Aspect (3) of the present disclosure pertains to the deadfront article of Aspect (2), wherein the semitransparent black layer is a rich black produced by mixing cyan, magenta, yellow, and black according to the CMYK color model.

Aspect (4) of the present disclosure pertains to the deadfront article of Aspect (3), wherein the black level is at least 50%.

Aspect (5) of the present disclosure pertains to the deadfront article of Aspect (2), wherein the semitransparent black layer is a composite black produced by mixing only cyan, magenta, and yellow according to the CMYK color model.

Aspect (6) of the present disclosure pertains to the deadfront article of any of the preceding Aspects (1) through (6), wherein the semitransparent black layer is a neutral black according to the CIE L*a*b* color space, wherein one or both of a* and b* are in a range from about −2 to about 2.

Aspect (7) of the present disclosure pertains to the deadfront article of Aspect (6), wherein L* is from 0 to 40.

Aspect (8) of the present disclosure pertains to the deadfront article of Aspect (7), wherein L* is from 5 to 20.

Aspect (9) of the present disclosure pertains to the deadfront article of any of the preceding Aspects (1) through (8), wherein a combination of the substrate and the semitransparent black layer comprise an average transmittance in a range from about 1 to about 40% along a wavelength range from about 400 nm to about 700 nm.

Aspect (10) of the present disclosure pertains to the deadfront article of any of the preceding Aspects (1) through (9), wherein the semitransparent black layer has an average thickness of up to 5 μm.

Aspect (11) of the present disclosure pertains to the deadfront article of any of the preceding Aspects (1) through (10), wherein the semitransparent black layer has an average thickness of at least 1 μm.

Aspect (12) of the present disclosure pertains to the deadfront article of any of the preceding Aspects (1) through (11), further comprising an opaque layer coated onto at least a portion semitransparent black layer, wherein the opaque layer has an optical density of greater than 3.

Aspect (13) of the present disclosure pertains to the deadfront article of Aspect (12), wherein the opaque layer is arranged on the semitransparent black layer in such a way as to define a portion of a graphic or a logo.

Aspect (14) of the present disclosure pertains to the deadfront article of any of the preceding Aspects (1) through (13), wherein the substrate comprises an average thickness between the first surface and the second surface in a range from 0.05 mm to 2 mm.

Aspect (15) of the present disclosure pertains to the deadfront article of any of the preceding Aspects (1) through (14), further comprising a functional layer located on the first surface of the glass layer.

Aspect (16) of the present disclosure pertains to the deadfront article of Aspect (15), wherein the surface function layer has an average thickness of 5 nm to 750 nm.

Aspect (17) of the present disclosure pertains to the deadfront article of Aspect (15) or (16), wherein the surface function layer provides at least one of glare reduction, scratch resistance, antireflection, half-mirror coating, or easy-to-clean surface.

Aspect (18) of the present disclosure pertains to the deadfront article of any of the preceding Aspect (1) through (17), wherein the substrate comprises a strengthened glass material.

Aspect (19) of the present disclosure pertains to the deadfront article of any of the preceding Aspects (1) through (18), wherein the glass layer is curved comprising a first radius of curvature.

Aspect (20) of the present disclosure pertains to the deadfront article of Aspect (19), wherein the first radius of curvature is in a range from about 60 mm to about 1500 mm.

Aspect (21) of the present disclosure pertains to the deadfront article of Aspect (19) or (20), wherein substrate comprises a second radius of curvature different from the first radius of curvature.

Aspect (22) of the present disclosure pertains to the deadfront article of any of Aspects (19) to (21), wherein the substrate comprises a glass and is cold-formed to the curved shape.

Aspect (23) of the present disclosure pertains to the deadfront article of any of the preceding Aspects (1) through (22), wherein a maximum thickness of the substrate measured between the first surface and the second surface is less than or equal to 1.5 mm.

Aspect (24) of the present disclosure pertains to the deadfront article of any of the preceding Aspects (1) through (23), wherein a maximum thickness of the substrate measured between the first surface and the second surface is 0.3 mm to 0.7 mm.

Aspect (25) of the present disclosure pertains to the deadfront article of any of the preceding Aspects (1) through (24), wherein the substrate has a width and a length, wherein the width is in a range from about 5 cm to about 250 cm, and the length is from about 5 cm to about 250 cm.

Aspect (26) of the present disclosure pertains to a display device having a deadfront, the display device comprising: a substrate; a semitransparent black layer disposed on a first surface of the substrate; and a light source positioned on a same side of the substrate as the first surface such that the semitransparent black layer is disposed between the substrate and the light source; wherein the semitransparent black layer is disposed on the second surface of the substrate with a printer using a CMYK color model.

Aspect (27) of the present disclosure pertains to the display device of Aspect (26), wherein the semitransparent black layer is a rich black produced by mixing cyan, magenta, yellow, and black according to the CMYK color model.

Aspect (28) of the present disclosure pertains to the display device of Aspect (27), wherein the black level is at least 50%.

Aspect (29) of the present disclosure pertains to the display device of Aspect (26), wherein the semitransparent black layer is a composite black produced by mixing only cyan, magenta, and yellow according to the CMYK color model.

Aspect (30) of the present disclosure pertains to the display device of any of Aspects (26) to (29), wherein the semitransparent black layer is a neutral black according to the CIE L*a*b* color space, wherein one or both of a* and b* are in a range from about −2 to about 2.

Aspect (31) of the present disclosure pertains to the display device of Aspect (30), wherein L* is from 0 to 40.

Aspect (32) of the present disclosure pertains to the display device of Aspect (31), wherein L* is from 5 to 20.

Aspect (33) of the present disclosure pertains to the display device of any of Aspects (26) to (32), wherein a combination of the glass layer and the semitransparent black layer comprise an average transmittance in a range from about 1 to about 40% along a wavelength range from about 400 nm to about 700 nm.

Aspect (34) of the present disclosure pertains to the display device of any of Aspects (26) to (33), further comprising an opaque layer having an optical density of greater than 3.

Aspect (35) of the present disclosure pertains to the display device of Aspect (34), wherein the opaque layer and the semitransparent black layer together define the at least one icon.

Aspect (36) of the present disclosure pertains to the display device of any of Aspects (26) to (35), wherein the light source comprises a dynamic display positioned on the same side of the substrate as the first surface.

Aspect (37) of the present disclosure pertains to the display device of Aspect (36), wherein the dynamic display comprises at least one of an OLED display, LCD display, LED display or a DLP MEMS chip.

Aspect (38) of the present disclosure pertains to the display device of any of Aspects (26) to (37), wherein the display device is disposed on a vehicle dashboard, a vehicle center console, a vehicle climate or radio control panel, or a vehicle passenger entertainment panel.

Aspect (39) of the present disclosure pertains to the display screen of any of Aspects (26) to (38), wherein the substrate is formed from a strengthened glass material and comprises an average thickness between the first surface and a second surface opposite to the first surface in a range from 0.05 mm to 2 mm.

Aspect (40) of the present disclosure pertains to the display screen of Aspect (39), wherein the substrate comprises a radius of curvature of between 60 mm and 1500 mm along at least one of the first surface and the second surface.

Aspect (41) of the present disclosure pertains to a method of forming a curved deadfront for a display comprising: curving a deadfront article on a support having a curved surface, wherein the deadfront article comprises: a glass layer; and a semitransparent black layer disposed onto a first surface of the glass layer with a printer using a CMYK color model; securing the curved deadfront article to the support such that the deadfront conforms to the curved shape of the curved surface of the support; wherein during curving and securing the deadfront article, a maximum temperature of the deadfront article is less than a glass transition temperature of the glass layer.

Aspect (42) of the present disclosure pertains to the method of Aspect (41), wherein securing the curved deadfront article comprises: applying an adhesive between the curved surface of the support and a surface of the deadfront article; and bonding the deadfront article to the support surface of the frame with the adhesive during application of the force.

Aspect (43) of the present disclosure pertains to the method of Aspect (41) or (42), wherein the glass layer is strengthened.

Aspect (44) of the present disclosure pertains to the method of Aspect (43), wherein the glass layer comprises a second surface opposite the first surface and wherein a maximum thickness of the glass layer measured between the first surface and the second surface is less than or equal to 1.5 mm.

Aspect (45) of the present disclosure pertains to the method of any of Aspects (41) to (44), wherein during curing and securing the deadfront article, a maximum temperature of the deadfront article is less than 200 degrees C.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred. In addition, as used herein, the article “a” is intended to include one or more than one component or element, and is not intended to be construed as meaning only one.

It will be apparent to those skilled in the art that various modifications and variations can be made without departing from the spirit or scope of the disclosed embodiments. Since modifications, combinations, sub-combinations and variations of the disclosed embodiments incorporating the spirit and substance of the embodiments may occur to persons skilled in the art, the disclosed embodiments should be construed to include everything within the scope of the appended claims and their equivalents.

1. A deadfront article for a display comprising:
a substrate comprising:
a first surface on a viewer-side of the substrate; and
a second surface opposite the first surface; and
a semitransparent black layer disposed onto at least a first portion of the second surface of the substrate;
wherein the semitransparent black layer is configured to obscure the display when the display is inactive and to allow viewing of the display when the display is active.

2. (canceled)

3. (canceled)

4. The deadfront article of claim 1, wherein the black level is at least 50%.

5. The deadfront article of claim 1, wherein the semitransparent black layer is a composite black produced by mixing only cyan, magenta, and yellow according to the CMYK color model.

6. The deadfront article of claim 1, wherein the semitransparent black layer is a neutral black according to the CIE L*a*b* color space, wherein one or both of a* and b* are in a range from about −2 to about 2.

7. The deadfront article of claim 6, wherein L* is from 0 to 40.

8. (canceled)

9. The deadfront article of claim 1, wherein a combination of the substrate and the semitransparent black layer comprise an average transmittance in a range from about 1 to about 40% along a wavelength range from about 400 nm to about 700 nm.

10. The deadfront article of claim 1, wherein the semitransparent black layer has an average thickness of at least 1 μm up to 5 μm.

11. (canceled)

12. The deadfront article of claim 1, further comprising an opaque layer coated onto at least a portion semitransparent black layer, wherein the opaque layer has an optical density of greater than 3.

13. (canceled)

14. (canceled)

15. (canceled)

16. (canceled)

17. (canceled)

18. (canceled)

19. The deadfront article of claim 1, wherein the substrate is curved comprising a first radius of curvature.

20. (canceled)

21. The deadfront article of claim 19, wherein substrate comprises a second radius of curvature different from the first radius of curvature.

22. The deadfront article of claim 19, wherein the substrate comprises a glass layer and is cold-formed to the curved shape.

23. (canceled)

24. (canceled)

25. The deadfront article of claim 1, wherein the substrate has a width and a length, wherein the width is in a range from about 5 cm to about 250 cm, and the length is from about 5 cm to about 250 cm.

26. A display device having a deadfront, the display device comprising:
a substrate;
a semitransparent black layer disposed on a first surface of the substrate; and
a light source positioned on a same side of the substrate as the first surface such that the semitransparent black layer is disposed between the substrate and the light source;
wherein the semitransparent black layer is disposed on the second surface of the substrate with a printer using a CMYK color model.

27. (canceled)

28. (canceled)

29. (canceled)

30. The display device of claim 26, wherein the semitransparent black layer is a neutral black according to the CIE L*a*b* color space, wherein one or both of a* and b* are in a range from about −2 to about 2.

31. The display device of claim 30, wherein L* is from 0 to 40.

32. (canceled)

33. The display device of claim 26, wherein a combination of the glass layer substrate and the semitransparent black layer comprise an average transmittance in a range from about 1 to about 40% along a wavelength range from about 400 nm to about 700 nm.

34. The display device of claim 26, further comprising an opaque layer having an optical density of greater than 3.

35. (canceled)

36. The display device of claim 26, wherein the light source comprises a dynamic display positioned on the same side of the substrate as the first surface.

37. The display device of claim 36, wherein the dynamic display comprises at least one of an OLED display, LCD display, LED display or a DLP MEMS chip.

38. (canceled)

39. (canceled)

40. (canceled)

41. A method of forming a curved deadfront for a display comprising:
curving a deadfront article on a support having a curved surface, wherein the deadfront article comprises:
a glass layer; and
a semitransparent black layer disposed onto a first surface of the glass layer with a printer using a CMYK color model;
securing the curved deadfront article to the support such that the deadfront conforms to the curved shape of the curved surface of the support;
wherein during curving and securing the deadfront article, a maximum temperature of the deadfront article is less than a glass transition temperature of the glass layer.

42.-45. (canceled)
